(19) United States
(12) Patent Application Publication
(10) Pub. No.: US 2007/0026588 A1
(43) Pub. Date: Feb. 1, 2007

(54) METHOD OF FABRICATING A THIN FILM TRANSISTOR

(76) Inventors: Te-Hua Teng, Taoyuan County (TW); Chun-Hsiang Fang, Yilan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/161,259

(22) Filed: Jul. 28, 2005

(51) Int. Cl. H01L 21/00

(52) U.S. Cl. 438/166

(57) ABSTRACT

A method of fabricating a thin film transistor is provided. An amorphous silicon layer is formed on a substrate. Then, the amorphous silicon layer is transformed into a polysilicon layer. After that, a heat process is performed for repairing the lattice defects of the polysilicon layer. Then, an ion implantation process is performed on the polysilicon layer. A gate isolation layer is formed on the substrate to cover the polysilicon layer. Then, a gate electrode disposed above the polysilicon layer is formed on the gate isolation layer. After, a source and a drain are formed in the polysilicon layer, wherein a channel is formed between the source and the drain. A patterned dielectric layer exposing a portion of the source and the drain is formed on the substrate. A source electrode and a drain electrode electrically connected to the source and the drain respectively are formed on the patterned dielectric layer.

### BACKGROUND OF THE INVENTION

1. Field of the Invention

The present invention generally relates to a method of fabricating a thin film transistor. More particularly, the present invention relates to a method of fabricating a low temperature thin film transistor (LTPS-TFT).

2. Description of Related Art

Digital video or image devices have become popular products in daily life according to the development of optoelectronic technology. The display panel is a very important communication interface for man to acquire information and to control the operation of the devices from the acquired information.

The thin film transistor (TFT) is a driving device applied to the display panel. Wherein, a material of the channel layer of the TFT may comprise amorphous silicon (α-Si) or polysilicon. Now, the amorphous silicon is broadly used because it can be formed in a low temperature condition about 200˜300° C. But the electron mobility of the amorphous silicon is less than 1 cm2/Vsec. So, it means that the amorphous silicon TFT can not attain the demand of high speed devices. Compared with the amorphous silicon, the polysilicon (poly-Si) TFT has higher electron mobility (about 100˜1000 times than that of the amorphous silicon TFT) and better low temperature sensitivity, so it can be applied to high speed deices.

The temperature for forming the polysilicon is above 600° C., so, the poly-Si TFT generally utilizes quartz as the substrate. But the quartz is much more expensive than the glass substrate. So, the poly-Si TFT must utilize the glass substrate to reduce the cost, and the temperature for forming the polysilicon must be reduced to the tolerant temperature of the glass substrate (about 500° C.). Many low temperature polysilicon fabricating methods are adapted to form the channel layer, and the excimer laser annealing (ELA) and metal induced crystallization (MIC) are more valued.

But the polysilicon layers formed by the above mentioned methods have many lattice defects. So, if the ion implantation process is sequentially performed to the polysilicon layers, the doping elements would not be uniformly distributed in the polysilicon layer. Besides, when the ion activation process is performed after the ion implantation process, the concentration of the carriers would not be uniform due to the lattice defects and the characteristics of the LTPS-TFT would be worse.

In the conventional process, a repairing process is often performed after an activation process or the fabrication of the thin film transistor. The uniformity of the doping elements can be effectively improved if the lattice defects are repaired before the ion implantation process is performed, and the characteristics of the LTPS-TFT can be further improved, too. A method for reducing the lattice defects of the LTPS-TFT has been disclosed in Jpn. J. Appl. Phys. Vol. 39 (2000) pp.2492˜2496 and Jpn. J. Appl. Phys. Vol. 39 (2000) pp.3883˜3887. The method is to place the low temperature polysilicon layer in a stainless steel cavity after the ELA is performed and to make the low temperature polysilicon layer in a high pressure and high temperature moisture environment. The result shows that the electrical conductivity of the low temperature polysilicon layer can be improved and the lattice defects can be reduced, too.

### SUMMARY OF THE INVENTION

Accordingly, the present invention is directed to a method of fabricating a thin film transistor for manufacturing a thin film transistor having better characteristics.

According to an embodiment of the present invention, a method of fabricating a thin film transistor comprising the following steps is provided. First, an amorphous silicon layer is formed on a substrate. Then, the amorphous silicon layer is transformed into a polysilicon layer. After that, a heat process is performed on the polysilicon layer in order to repair the lattice defects of the polysilicon layer. Then, an ion implantation process is performed on the polysilicon layer. A gate isolation layer is formed on the substrate to cover the polysilicon layer. After, a gate electrode is formed on the gate isolation layer, wherein the gate electrode is disposed above the polysilicon layer. Then, a source and a drain are formed in the polysilicon layer below the two sides of the gate electrode, and a channel is formed between the source and the drain. A patterned dielectric layer is formed on the substrate, and the patterned dielectric layer exposes a portion of the source and the drain. Finally, a source electrode and a drain electrode are formed on the patterned dielectric layer, wherein the source electrode and the drain electrode are electrically connected to the source and the drain, respectively.

According to one embodiment of the invention, the heat process may utilize a high temperature gas with moisture, and the high temperature gas is selected from the group consisting of oxygen and nitrogen. The pressure of the high temperature gas is between 0.2 MPa and 1 MPa, and the temperature of the high temperature gas is between 100° C.˜300° C.

According to one embodiment of the invention, the above mentioned heat process can be a plasma treatment process. The reactive gas of the plasma treatment process can be oxygen or nitrogen. The temperature of the plasma treatment process is above 300° C., and the power of the plasma treatment process is above 2 KW.

According to one embodiment of the invention, before the amorphous silicon layer is formed on the substrate, the method further comprises a step of forming a buffer layer on the substrate.

According to one embodiment of the invention, before the heat process is performed, the method further comprises a step of patterning the polysilicon layer, to form a polysilicon island.

According to one embodiment of the invention, after the heat process and before the ion implantation process are performed, the method further comprises a step of patterning the polysilicon layer, to form a polysilicon island.

According to one embodiment of the invention, after the ion implantation process is performed and before the gate isolation layer is formed, the method further comprises a step of patterning the polysilicon layer, to form a polysilicon island.

According to one embodiment of the invention, the above mentioned method for transforming the amorphous silicon layer into a polysilicon layer may be an excimer laser annealing.

According to one embodiment of the invention, after the source and the drain are formed, the method further comprises a light doped drain ion implantation process, to form a light doped drain between the source and the drain and the channel.

According to one embodiment of the invention, after the source electrode and the drain electrode are formed, the method further comprises an ion activation process.

According to one embodiment of the invention, before the source and drain are formed, the method may further comprise an ion activation process.

In summary, the invention performs a heat process (using a high temperature gas with moisture or a plasma treatment process) to the polysilicon layer before the ion implantation process, to repair the lattice defects of the polysilicon layer. So, the doping elements can be uniformly distributed in the polysilicon layer after the heat process, to improve the characteristics of the thin film transistor.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A˜1F are cross sectional views showing a method of fabricating a thin film transistor according to one embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

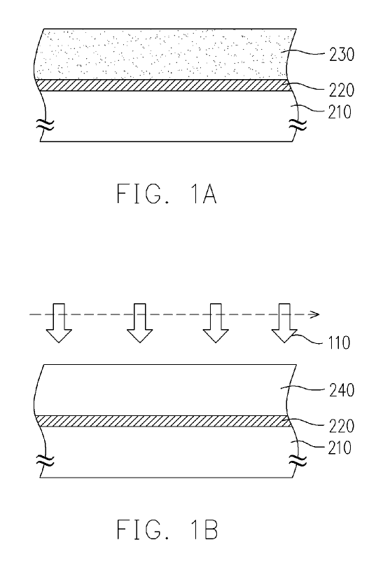

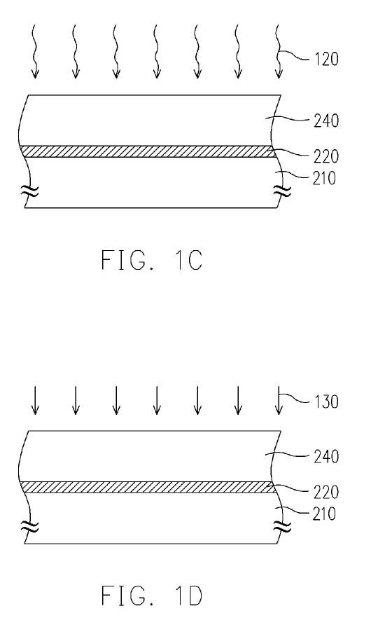

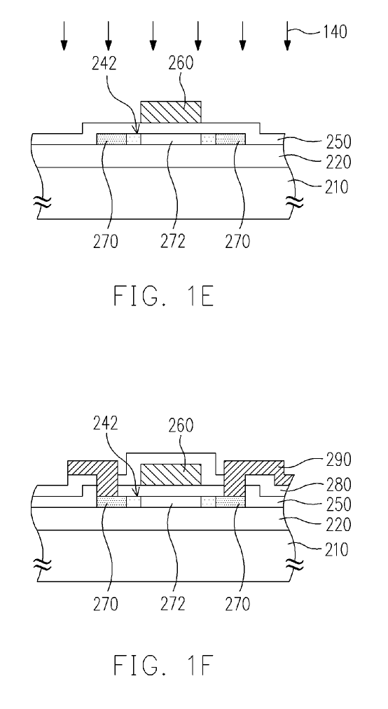

FIGS. 1A˜1F are cross sectional views showing a method of fabricating a thin film transistor according to one embodiment of the present invention.

Please refer to FIG. 1A, an amorphous silicon layer 230 is formed on a substrate 210. The amorphous silicon layer 230 can be formed by Chemical vapor deposition (CVD). Besides, before the amorphous silicon layer 230 is formed, a buffer layer 220 can be formed on the substrate 210 in advance. The buffer layer 220 can be stacked films made of silicon nitride layers and silicon dioxide layers, to improve the adhesion between the substrate 210 and the later formed polysilicon layer 240. Besides, the buffer layer 220 can avoid the impurities of the substrate 210 from contaminating the polysilicon layer 240.

As shown in FIG. 1B, the amorphous silicon layer 230 is transformed into the polysilicon layer 240. The amorphous silicon layer 230 can be transformed into the polysilicon layer 240 by an excimer laser annealing process 110. More specifically, the excimer laser annealing process 110 utilizes the excimer laser beams to expose the amorphous silicon layer 230 and makes the amorphous silicon layer 230 melt to become liquid silicon. After a period of time, the liquid silicon would cool down and recrystallize to become the polysilicon layer 240. But the polysilicon layer 240 still has discontinuous grain boundary, the discontinuous grain boundary would make the later formed doping elements be not distributed uniformly in the polysilicon layer 240.

Please refer to FIG. 1C, a heat process 120 is performed on the polysilicon layer 240 in order to repair the lattice defects of the polysilicon layer 240, so the later formed doping elements can easily diffuse in the polysilicon layer 240. For example, the heat process 120 can utilize a high temperature gas with moisture. The high temperature gas may comprise oxygen, nitrogen and the combination of them. Besides, the pressure of the high temperature gas is between 0.2 MPa and 1 MPa, and the temperature of the high temperature gas is between 100° C.˜300° C. Compared with the prior art, the invention may utilize oxygen and nitrogen to adjust the composition of the high temperature gas except to the moisture, to further repair the lattice defects of the polysilicon layer 240.

Besides, the heat process 120 can also be a plasma treatment process. The reactive gas of the plasma treatment process may be oxygen or nitrogen. The temperature of the plasma treatment process may be above 300° C., and the power of the plasma treatment process may be above 2 KW. The plasma treatment process can reduce the lattice defects of the polysilicon layer 240 as the same.

Please refer to FIG. 1D, an ion implantation process 130 is performed on the polysilicon layer 240. The ion implantation process 130 ionizes the doping elements first, and then accelerates the doping elements to implant them into the polysilicon layer 240. In other words, the ion implantation process 130 is a channel doping process. The doping elements would be uniformly diffused in the polysilicon layer 240 because of the heat process 120. More specifically, after the heat process 120, the polysilicon layer 240 is patterned to form a polysilicon island 242.

It should be noted that in other embodiment, the polysilicon layer 240 is patterned to form a polysilicon island 242 before the heat process 120. Alternatively, in another embodiment, the polysilicon layer 240 is patterned to form a polysilicon island 242 after the heat process 120 and before the ion implantation process 130. In brief, the embodiment only limits the heat process 120 to be performed before the ion implantation process 130. The step of forming the polysilicon island 242 can be performed before or after the heat process 120 or the ion implantation process 130.

Please refer to FIG. 1E, a gate isolation layer 250 is formed on the substrate 210 to cover the polysilicon island 242. The gate isolation layer 250 can be formed by Chemical vapor deposition. Then, a gate electrode 260 is formed on the gate isolation layer 250, wherein the gate electrode 260 is disposed above the polysilicon island 242. Besides, the gate electrode 260 may be formed by the conventional photolithography process, so the process is not repeated herein.

As shown in FIG. 1E, a source 270 and a drain 270 are formed in the polysilicon island 242 below the two sides of the gate electrode 260, and a channel 272 is formed between the source 270 and the drain 270. More specifically, the source 270 and the drain 270 can be formed by an ion implantation process 140 using the gate electrode 260 as a mask. It should be noted that after the source 270 and the drain 270 are formed, a light doped drain ion implantation process can be performed to form a light doped drain (not shown) between the source 270 and the drain 270 and the channel 272, to improve the hot carrier effect.

Please refer to FIG. 1F, after the source 270 and the drain 270 are formed, a patterned dielectric layer 280 is formed on the substrate 210, and the patterned dielectric layer 280 exposes a portion of the source 270 and the drain 270. The patterned dielectric layer 280 may be formed by the conventional deposition and photolithography process, and the conventional processes are not repeated herein. After that, a source electrode 290 and a drain electrode 290 are formed on the patterned dielectric layer 280, wherein the source electrode 290 and the drain electrode 290 are electrically connected to the source 270 and the drain 270, respectively. The fabrication of the thin film transistor is finished. Besides, the source electrode 290 and the drain electrode 290 can be the contact for connecting with the later formed pixel electrodes or peripheral circuits.

It should be noted that before the source electrode 290 and the drain electrode 290 are formed, an ion activation process can be performed in order to make the doping ions be distributed uniformly. Besides, the heat process can be a rapid thermal annealing (RTA) process, a furnace annealing (FA) process or other heat processes.

Because the heat process 120 is performed on the polysilicon island 242, the doping elements doped by the above mentioned process can be more uniformly distributed. Besides, in another embodiment, an ion activation process can be performed after the source 270 and the drain 270 are formed.

In summary, the invention performs a heat process (using a high temperature gas with moisture or a plasma treatment process) to the polysilicon layer before the ion implantation process, to repair the lattice defects of the polysilicon layer. So, the doping elements can easily diffuse in the polysilicon layer. In other words, the doping elements can be more uniformly distributed in the polysilicon layer after the ion activation process.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating a thin film transistor, comprising:
forming an amorphous silicon layer on a substrate;
transforming the amorphous silicon layer into a polysilicon layer;
performing a heat process to the polysilicon layer, to repair lattice defects of the polysilicon layer;
performing an ion implantation process to the polysilicon layer;
forming a gate isolation layer on the substrate to cover the polysilicon layer;
forming a gate electrode on the gate isolation layer, wherein the gate electrode is placed above the polysilicon layer;
forming a source and a drain in the polysilicon layer below the two sides of the gate electrode, wherein a channel is formed between the source and the drain;
forming a patterned dielectric layer on the substrate, wherein the patterned dielectric layer exposes a portion of the source and the drain; and
forming a source electrode and a drain electrode on the patterned dielectric layer, wherein the source electrode and the drain electrode are electrically connected to the source and the drain, respectively.

2. The method of fabricating a thin film transistor according to claim 1, wherein the heat process utilizes a high temperature gas with moisture.

3. The method of fabricating a thin film transistor according to claim 2, wherein the high temperature gas is selected from the group consisting of oxygen and nitrogen.

4. The method of fabricating a thin film transistor according to claim 2, wherein the pressure of the high temperature gas is between 0.2 MPa and 1 MPa.

5. The method of fabricating a thin film transistor according to claim 2, wherein the temperature of the high temperature gas is between 100° C.˜300° C.

6. The method of fabricating a thin film transistor according to claim 1, wherein the heat process comprises a plasma treatment process.

7. The method of fabricating a thin film transistor according to claim 6, wherein the reactive gas of the plasma treatment process comprises oxygen or nitrogen.

8. The method of fabricating a thin film transistor according to claim 6, wherein the temperature of the plasma treatment process is above 300° C.

9. The method of fabricating a thin film transistor according to claim 6, wherein the power of the plasma treatment process is above 2 KW.

10. The method of fabricating a thin film transistor according to claim 1, wherein before the amorphous silicon layer is formed on the substrate, the method further comprises a step of forming a buffer layer on the substrate.

11. The method of fabricating a thin film transistor according to claim 1, wherein before the heat process is performed, the method further comprises a step of patterning the polysilicon layer, to form a polysilicon island.

12. The method of fabricating a thin film transistor according to claim 1, wherein after the heat process and before the ion implantation process are performed, the method further comprises a step of patterning the polysilicon layer, to form a polysilicon island.

13. The method of fabricating a thin film transistor according to claim 1, wherein after the ion implantation process is performed and before the gate isolation layer is formed, the method further comprises a step of patterning the polysilicon layer, to form a polysilicon island.

14. The method of fabricating a thin film transistor according to claim 1, wherein the method for transforming the amorphous silicon layer into a polysilicon layer comprises an excimer laser annealing.

15. The method of fabricating a thin film transistor according to claim 1, wherein after the source and the drain are formed, the method further comprises a light doped drain ion implantation process, to form a light doped drain between the source and the drain and the channel.

16. The method of fabricating a thin film transistor according to claim 1, wherein before the source electrode and the drain electrode are formed, the method further comprises an ion activation process.

17. The method of fabricating a thin film transistor according to claim 1, wherein after the source and drain are formed, the method further comprises an ion activation process.
